(19) United States
(12) Patent Application Publication
(10) Pub. No.: US 2023/0238683 A1
(43) Pub. Date: Jul. 27, 2023

(54) ELECTRONIC DEVICE

(71) Applicant: Apple Inc., Cupertino, CA (US)

(72) Inventors: Steven C. Roach, Martinez, CA (US); Eric T. Chiang, San Francisco, CA (US); YoungHoon Kim, San Jose, CA (US); Maegan K. Spencer, La Honda, CA (US); Michael R. Parker, Aptos, CA (US); Christopher M. Werner, San Jose, CA (US); Ryan C. Perkins, San Francisco, CA (US); Bora Inci, Cupertino, CA (US); Sherry Tang, Santa Clara, CA (US); Tyler S. Atura Bushnell, San Francisco, CA (US); Daniela Deschamps, Palo Alto, CA (US); Colin M. Ely, Sunnyvale, CA (US); Devon K. Copeland, Santa Clara, CA (US); Ming Kun Shi, Morgan Hill, CA (US)

(21) Appl. No.: 17/934,478

(22) Filed: Sep. 22, 2022

Related U.S. Application Data
(60) Provisional application No. 63/374,735, filed on Sep. 6, 2022.
(60) Provisional application No. 63/267,098, filed on Jan. 24, 2022.

(51) Int. Cl. H01Q 1/22; H01Q 1/40; H05K 5/00

(52) U.S. Cl. CPC H01Q 1/2266; H01Q 1/40; H05K 5/0013; G06F 1/163

(57) ABSTRACT

A portable electronic device can include a housing defining an internal volume and an opening. The device can also include a rear cover disposed in the opening, with an inner surface of the rear cover defining the internal volume, and a conductive antenna component embedded within the rear cover.

### CROSS-REFERENCE TO RELATED APPLICATION(S)

This claims priority to U.S. Provisional Patent Application No. 63/374,735, filed 6 Sep. 2022, and entitled “ELECTRONIC DEVICE,” and to U.S. Provisional Patent Application No. 63/267,098, filed 24 Jan. 2022, and entitled “ELECTRONIC DEVICE,” the disclosures of which are hereby incorporated by reference in their entireties.

### FIELD

The described embodiments relate generally to electronic devices. More particularly, the present embodiments relate to wearable electronic devices.

### BACKGROUND

Electronic devices are increasingly being designed with device portability in mind, for example, to allow users to use these devices in a wide variety of situations and environments. In the context of wearable devices, these devices can be designed to include many different functionalities and to be operated in many different locations and environments. The components of an electronic device, for example, the processors, memory, antennas, display, and other components can partially determine a level of performance of the electronic device. Further, the arrangement of these components with respect to one another in the device can also determine the level of performance of the electronic device.

Continued advances in electronic devices and their components have enabled considerable increases in performance. Existing components and structures for electronic devices can, however, limit the levels of performance of such devices. For example, while some components can achieve high levels of performance in some situations, the inclusion of multiple components in devices sized to enhance portability can limit the performance of the components, and thus, the performance of the device. Consequently, further tailoring an arrangement of components for electronic devices to provide additional or enhanced functionality, without introducing or increasing undesirable device properties, can be desirable.

### SUMMARY

In at least one example of a portable electronic device described herein, a housing can define an internal volume and an opening. The device can also include a rear cover disposed in the opening, with an inner surface of the rear cover defining the internal volume, and a conductive antenna component embedded within the rear cover.

In at least one example, the conductive antenna component can be disposed outside the internal volume. In at least one example, the antenna component is entirely embedded within the rear cover. In at least one example, an outer surface of the rear cover can define an external surface of the electronic device. In at least one example, the rear cover can extend across a thickness defined between the outer surface and the inner surface and the antenna component can be disposed within the thickness. In at least one example, the rear cover can include plastic. In at least one example, the rear cover can define a first opening and the antenna component can define a second opening corresponding in position with the first opening.

In at least one example of the present disclosure, an electronic device housing can include a sidewall defining a rear opening, a rear cover disposed in the opening and defining an external surface, and a metal sheet disposed within the rear cover. In at least one example, the rear cover can include a plastic body and a hard coat layer disposed on the plastic body and defining the external surface.

In at least one example, the metal sheet can include an antenna component. In one example, the antenna component can be embedded within the plastic body. In one example, the antenna component can be insert molded into the plastic body. In one example, the plastic body can include glass-filled nylon. In one example, the electronic device housing can further include a primer layer disposed between the hard coat layer and the plastic body. In one example, the hard coat layer can include a UV-curable hard coat material. In at least one example, the hard coat layer can include a UV-curable mono-coat disposed directly on the plastic body. In one example, the UV-curable mono-coat can include an indentation hardness between about 190 N/mm² and about 250 N/mm². In one example, the UV-curable mono-coat can include an acrylic polyol with a glass transition temperature of about 50° C. In at least one example, the UV-curable mono-coat can include acrylic monomer(s) and an acrylic polyol resin that contains between about 10% and about 20% (hydroxyethyl)methacrylate, and between about 3% and about 7% methacrylic acid by volume and an acrylic monomer.

In at least one example of the present disclosure, a rear cover of an electronic device can include an antenna component including a metal sheet and a non-conductive body molded around the antenna component. In such an example, an external surface of the body is curved and the metal sheet can be curved to correspond to the external surface.

In at least one example, the metal sheet can include a stepped curved geometry. In one example, the stepped curved geometry can include an outer curved portion and an inner curved portion. In one example, the metal sheet can further include an intermediate step portion disposed between the outer curved portion and the inner curved portion. In one example, the inner curved portion is disposed lower than the outer curved portion.

### BRIEF DESCRIPTION OF THE DRAWINGS

The disclosure will be readily understood by the following detailed description in conjunction with the accompanying drawings, wherein like reference numerals designate like structural elements, and in which:

FIG. 1A shows a perspective view of an electronic device;

FIG. 1B shows a bottom exploded view of the electronic device of FIG. 1A;

FIG. 2 shows an exploded view of an electronic device;

FIG. 3A shows an exploded view of a portion of an electronic device;

FIG. 3B shows an exploded view of a portion of an electronic device;

FIG. 3C shows a cross-sectional view of a rear cover of an electronic device;

FIG. 4 shows a top plan view of an electronic device;

FIG. 5A shows a cross-sectional view thereof;

FIG. 5B shows another cross-sectional view thereof;

FIG. 5C shows a close-up view of the cross-sectional view shown in FIG. 5A;

FIG. 6A shows a cross-sectional view of the device shown in FIG. 4;

FIG. 6B shows another cross-sectional view thereof;

FIG. 6C shows a close-up view of the cross-sectional view shown in FIG. 6A;

FIG. 7 shows a perspective view of a rear cover of an electronic device;

FIG. 8 shows a cross-sectional view thereof; and

FIG. 9 shows a cross-sectional view of the rear cover shown in FIG. 7.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

The architecture and components of the electronic devices described herein can allow for configurations and designs that can maximize the number of functions and performance of a portable or wearable electronic device, while also allowing for the use of relatively low cost or abundant materials, and the reduction of manufacturing and assembly complexity and costs. In addition, some components of the compact, portable devices described herein can be delicate and sensitive such that the components need to be arranged and configured to be protected. In some examples, components arranged together within the device can serve more than one function, lending to a more compact arrangement. In this way, the tailoring and arrangement of components for electronic devices described herein can provide additional or enhanced functionality, without introducing or increasing undesirable device properties or reduced performance.

For example, in at least one portable electronic device described herein, a housing can define an internal volume and an opening. The device can also include a rear cover disposed in the opening, with an inner surface of the rear cover defining the internal volume, and a conductive antenna component embedded within the rear cover. The antenna component can include a conductive metal material in the form of a sheet metal. The rear cover can include a plastic body within which the sheet metal of the antenna component can be insert molded. In this way, the antenna component can be physically protected by the surrounding body of the rear cover and the antenna can serve to strengthen or stiffen the rear cover. In at least one example, because of the strengthening functionality of the antenna component, the rear cover can be formed using lighter, cheaper, more abundant materials such as plastic without sacrificing durability and strength. For example, the rear cover can include glass-filled nylon. Glass-filled nylons and other plastic materials can also provide aesthetic advantages as the colors of the plastic materials can vary.

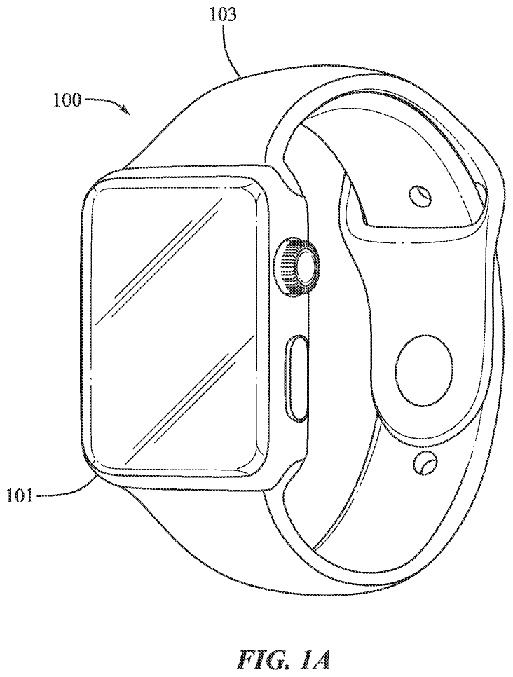

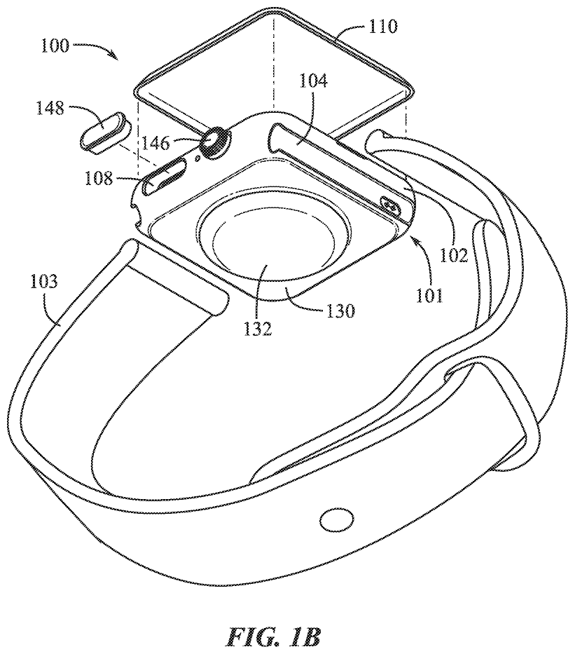

These and other embodiments are discussed below with reference to FIGS. 1A-9. However, those skilled in the art will readily appreciate that the detailed description given herein with respect to these Figures is for explanatory purposes only and should not be construed as limiting.

FIG. 1A shows an example of an electronic device 100. The electronic device shown in FIG. 1A is a watch, such as a smartwatch. The smartwatch of FIG. 1A is merely one representative example of a device that can be used in conjunction with the systems and methods disclosed herein. Electronic device 100 can correspond to any form of wearable electronic device, a portable media player, a media storage device, a portable digital assistant (“PDA”), a tablet computer, a computer, a mobile communication device, a GPS unit, a remote control device, or other electronic device. The electronic device 100 can be referred to as an electronic device, or a consumer device. In some examples, the electronic device 100 can include a body 101 that can carry operational components, for example, in an internal volume at least partially defined by a housing of the body. The electronic device 100 can also include a strap 103, or another retaining component that can secured the device 100 to a body of a user, as desired. Further details of the electronic device are provided below with reference to FIG. 1B.

Referring now to FIG. 1B, the electronic device 100 can include a body 101 having a housing 102 and a cover 110 attached to the housing 102. The housing 102 can substantially define at least a portion of an exterior surface of the device 100. The cover 110 can include a ceramic material such as sapphire, glass, plastic, or any other substantially transparent material, component, or assembly. The cover 110 can cover or otherwise overlay a display, a camera, a touch sensitive surface such as a touchscreen, or other component of the device 100. The cover 110 can define a front exterior surface of the device 100. Together, the housing 102 and the cover 110 can substantially define the exterior surface of the device 100.

In some examples, the housing 102 can include a component 130 that defines at least an exterior surface of the device 100. The component 130 can be referred to as a back case or a rear cover, and in some examples, can be attached to one or more other components, such as the housing 102. The component 130 can be attached to the housing 102 by any method known in the art or developed in the future, such as adhesive bonding, brazing, welding, overmolding, interference fitting, or other securing methods.

The rear cover 130 can define one or more apertures or through holes. A transparent material 132 can be disposed in the one or more apertures. In some examples, the transparent material 132 can be visually transparent and can include any transparent including a ceramic material such as sapphire. The transparent material 132 can provide visual and electromagnetic access to an exterior environment for one or more components of the device 100, as described herein.

The housing 102 can include one or more features to receive or couple to other components of the device 100. For example, housing 102 can include features, such as an indentation 104 to receive strap 103, and an aperture 108 to receive a button 148. The housing can also define one or more apertures to receive additional input components, such as a dial or a crown 146.

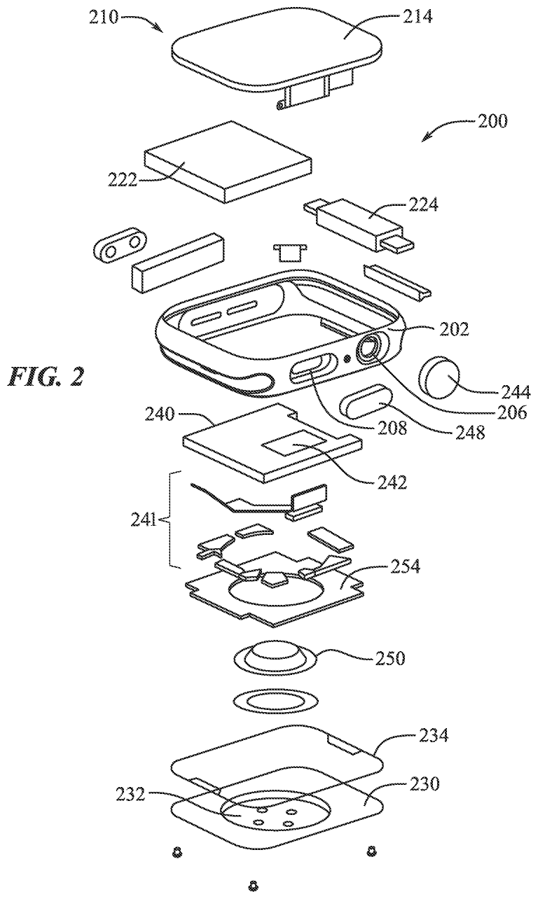

The device 100 is merely one example of an electronic device 100. Additional electronic devices and designs thereof, are expressly contemplated. Further details of example electronic devices and components are provided below with reference to FIG. 2.

FIG. 2 illustrates an exploded view of a smartwatch 200 that can be substantially similar to, and can include some or all of the features of the devices described herein, such as electronic device 100. The device 200 can include a housing 202, a display assembly 210, and a rear cover 230. Together, the housing 202, the display assembly 210, and the rear cover 230 can define an exterior surface and an internal volume of the device 200. In addition, an electromagnetically transparent component 232 can be disposed in an opening defined by the rear cover 330. The electromagnetically transparent component 232 can be bonded, adhered, or otherwise connected to the rear cover 330 as shown in FIG. 2.

The housing 202 can be a substantially continuous or unitary component, and can define one or more openings 204, 206, 208 to receive components of the electronic device 200 and/or to provide access to an internal portion of the electronic device 200. In some examples, the device 200 can include input components such as one or more buttons 248 and/or a crown 244 that can be disposed in the openings 206, 208. A microphone can be disposed in the internal volume such that it is in communication with the external or ambient environment through the opening 204.

The display assembly 210 can be received by and can be attached to the housing 202. The display assembly can include a cover 214 including a transparent material, such as plastic, glass, and/or ceramic. The display assembly 210 can also include a display stack 212 that can include multiple layers and components, each of which can perform one or more desired functions. For example, the display stack 212 can include a display layer 212 that can include a touch detection layer or component, a force sensitive layer or component, and one or more display layers or components that can include one or more pixels and/or light emitting portions to display visual content and/or information to a user. In some examples, the display layer or component 212 can include a liquid crystal display (LCD), a light emitting diode (LED) display, an organic light emitting diode (OLED) display, and/or any other form of display. The display layer 212 can also include one or more electrical connectors to provide signals and/or power to the display layer 212 from other components of the device 200.

In some examples, the device 200 can include a gasket or a seal 216 that can be disposed between the display assembly 210 and the housing 202 to substantially define a barrier to the ingress of liquids or moisture into the internal volume from the external environment at the location of the seal 216. As described herein, the seal 216 can include polymer, metal, and/or ceramic materials. The device 200 can also include a seal 234 that can be disposed between the housing 202 and the rear cover 230 to substantially define a barrier to the ingress of liquids or moisture into the internal volume from the external environment at the location of the seal 234. As described herein, the seal 234 can include polymer, metal, and/or ceramic materials. The seal 234 can be substantially similar to and can include some or all of the features of the seal 216.

The device 200 can also include internal components, such as a haptic engine 224, a battery 222, and a logic board 240, also referred to as a main logic board 240, that can include a system in package (SiP) 242 disposed thereon, including one or more integrated circuits, such as processors, sensors, and memory. The SiP 242 can also include a package.

In some examples, internal components can be disposed below the main logic board 240 and can be disposed at least partially in a portion of the internal volume defined by the rear cover 230. For example, the device 200 can include an electromagnetic shielding component, otherwise referred to as an e-shield 252, that can shield other components in the device 200 from electromagnetic radiation from the ambient environment and/or as emitted by other components in the device 200. The device 200 can also include a second logic board 250 that can be in communication with one or more sensors or emitters of the device 200, for example, to receive information or signals from an external environment. In some examples, the second logic board 250 can also include a SiP 242. In some examples, the device 200 can include one or more wireless antennas, such as antenna 254, which can be in electrical communication with one or more other components of the device 200. In some examples, the antenna 254 can receive and/or transmit wireless signals at one or more frequencies and can be, for example, one or more of a cellular antenna such as an LTE antenna, a Wi-Fi antenna, a Bluetooth antenna, a GPS antenna, a multi-frequency antenna, and the like. The antenna 254 can be communicatively coupled to one or more additional components of the electronic device 200. The exploded view of FIG. 2 also shows one or more circuitry components 241, which can include one or more conductive flexes, electrical wires, RF antenna leads, and other electrical connection components configured to connect the antenna component 254 to the logic board 240 of the device 200.

The internal components can be disposed within the internal volume defined at least partially by the housing 202, and can be affixed to the housing 202 via internal surfaces, attachment features, threaded connectors, studs, posts, or other features, that are formed into, defined by, or otherwise part of the housing 202 and/or the cover 214 and/or rear cover 330.

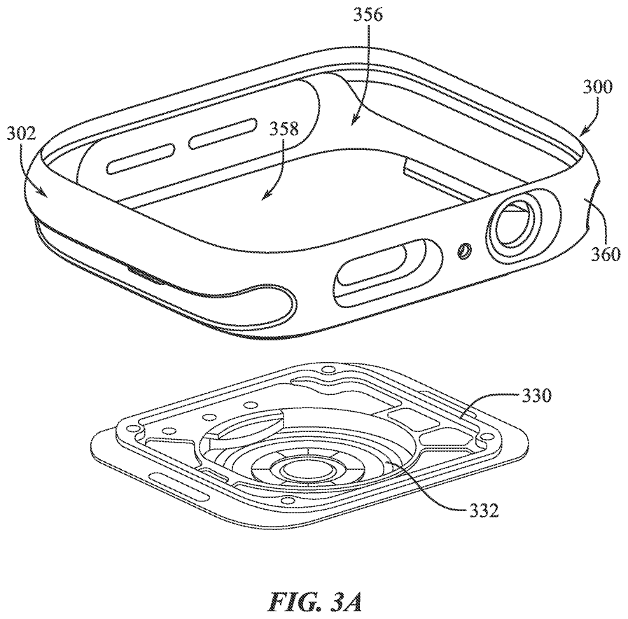

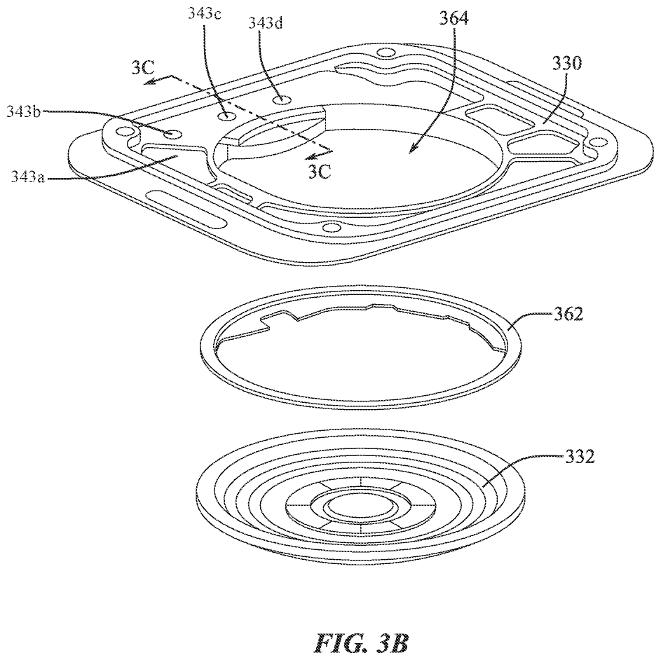

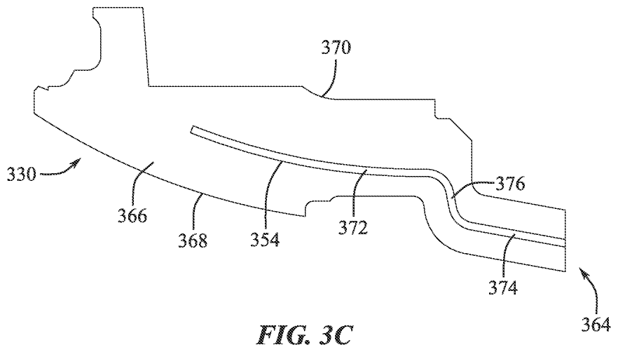

Any number or variety of components in any of the configurations described with reference to FIGS. 1A-2 can be included alone or in combination in any other electronic device described herein with reference to other figures. The components can include any combination of the features described herein and can be arranged in any of the various configurations described herein. The structure and arrangement of components of a device, as well as the concepts regarding the use and operation of the components can apply not only to the specific examples discussed herein, but to any number of embodiments in any combination. Various examples of electronic devices and electronic device components including having various features in various arrangements are described below, with reference to FIGS. 3A-9.

FIG. 3A shows an exploded view of a portion of an exemplary device 300, including a housing 302 forming sidewalls 360 and a rear cover 332. FIG. 3B shows an exploded view of the rear cover 330 and FIG. 3C shows a cross-sectional view of the rear cover 330 at a location through the rear cover 330 as indicated in FIG. 3B. Referring to FIG. 3A, the sidewalls 360 of the housing 302 can define an internal volume 356 and an opening 358. In the orientation of the device 300 shown in FIG. 3A, the opening 358 can be a rear opening 358 and the rear cover 330 can be disposed in the rear opening 358 when the device 300 is assembled. In at least one example, an electromagnetically transparent component 332 can be secured to the rear cover 330. In at least one example, the electromagnetically transparent component 332 can be disposed in an opening defined by the rear cover 330.

FIG. 3B shows an exploded view of the rear cover 330 and electromagnetically transparent component 332. As noted, the rear cover 330 can define an opening 364 in which the electromagnetically transparent component 332 can be disposed when assembled. In addition, in at least one example, an adhesive layer, component, or ring 362 can secure the electromagnetically transparent component 332 to the rear cover 330 in the opening 364. One or more other securement means can also secure the electromagnetically transparent component 332 to the rear cover 330, including adhesives and glues such as pressure sensitive adhesives, chemical bonding, interlocking mechanical structures including mechanical securing mechanisms such as screws, latches, fasteners, or other mechanical securing means, and the like. In at least one example, the adhesive component 362 can include a dispensed glue.

In addition, FIG. 3B shows access points 343a, 343b, 343c, and 343d through which the one or more circuitry components 241 shown in FIG. 2 can extend through the rear cover 330 to make electrical contact with the antenna component 354 disposed within the rear cover 330. The number, size, shape, and position of the access points 343a-d can vary in one or more other examples. The access points 343a-d can include apertures defined by the rear cover 330 through which circuitry component can extend to make contact with the conductive material of the antenna component 354 embedded within the rear cover 330, as shown in FIG. 3C. The circuitry components 241 noted above can contact the embedded antenna component 354 to form a radio-frequency (RF) circuit within the devices described herein. The RF circuit and antenna component 354 can form a functioning antenna configured to receive, process, and send electromagnetic signals.

FIG. 3C shows a cross-sectional view of the rear cover 330 at a location through the rear cover 330 as indicated in FIG. 3B. As shown, the rear cover 330 can disposed in the opening 358 with an inner surface 370 of the rear cover 330 defining the internal volume 356. In at least one example, the antenna component 354 can be embedded within the rear cover 330.

The embedded antenna component 354 can increase a vertical distance (also referred to as a “Z-distance”) between the antenna component 354 and a grounding plane relative thereto. Rather than being disposed within the internal volume, the embedded antenna component 354 is disposed further downward into the rear cover 330 to increase the Z-distance of the antenna. Embedding the antenna component 354 into the rear cover 330 also reduces interference with other components. In addition, the rear cover 330 can physically protect the antenna component 354 disposed therein by surrounding the antenna component 354 so that other components or objects do not come into contact with the antenna component 354 during normal use or during a drop event or when the device 300 is subjected to outside forces that could be damaging.

In addition, in at least one example, the antenna component 354 can includes material or be formed into a shape that is stiffer and/or stronger than the material and configuration of the rear cover 330 alone. In this way, in at least one example, in addition to the antenna functionalities of the antenna component 354, the antenna component 354 can also serve to structurally support, strengthen, and/or stiffen the rear cover. The embedded antenna component 354 thus strengthens the rear cover 330 and provides a more durable, longer lasting device 300.

In addition, in at least one example, the presence of the antenna component 354, which can include conductive material embedded within the rear cover, can dissipate eddy currents. This can be advantageous during electrical charging of the battery of the device 300 in examples where the device 300 includes a charging coil disposed in the internal volume 356 of the device 300.

As seen in FIG. 3C, in at least one example of the device 300, the antenna component 354 can be disposed or embedded entirely within the rear cover 330 such that the rear cover 330 cover both opposing sides of the antenna component 354 and from one edge to the other. In at least one example, the inner surface 370 of the rear cover 330 at least partially defines the internal volume 356 of the device 300 such that the antenna component 354 disposed within the rear cover 330 is disposed outside the internal volume 356. In at least one example, the antenna component 354 can be insert molded into the body 366 of the rear cover 330. For example, during manufacturing, a first shot of the body 366 of the rear cover 330 can be molded then the antenna component 354 can be placed, molded, or adhered against the first shot of the rear cover 330. Then, in at least one example during manufacturing, a second shot of the body 366 of the rear cover 330 can be molded over the antenna component 354 and the first shot of the body 366 of the rear cover 330.

In at least one example, an outer surface 368 of the rear cover 330 defines an external surface of the electronic device 300 and the rear cover 330 extends across a thickness defined between the outer surface 368 and the inner surface 370. According to this example, the antenna component 354 is disposed within the thickness of the rear cover 330. As shown in FIG. 3C, a body 366 of the rear cover can include the rear cover 330 disposed between the outer surface 368 and the inner surface 370. As noted above, the antenna component 354 can include conductive material such as one or more metal materials, conductive ceramic materials, and/or one or more other conductive materials. The body 366 of the rear cover 330 can include a non-conductive material, including one or more plastic materials or other polymer materials.

The material of the rear cover 330 can be selected to maximize bond strength with the electromagnetically transparent component 332 bonded to the rear cover 330 using the glues or other adhesives discussed above.

According to one example of the device 300, the rear cover 330 includes an antenna component that includes a metal sheet 354 and a non-conductive body 366 molded around the antenna component 354. In such an example, an external surface 368 of the body 366 is curved as shown in FIG. 3C. In at least one example, the curvature of the external surface 368 is convex. In at least one example, the metal sheet 354 of the antenna component can also be curved to correspond to the curvature of external surface 368. For example, the metal sheet 354 of the antenna component 354 can be convex. The terms “correspond” or “corresponding” used herein can be used to denote a similar orientation of curvature, for example convex or concave, but does not denote an exact similarity in radius of curvature or dimensions. Rather, the corresponding nature of the curvature of the metal sheet 354 of the antenna component denotes that the metal sheet 354 follows a general curvature and configuration of the external surface 368 of the external surface 368 of the rear cover 330.

In at least one example, the metal sheet 354 includes a stepped curved geometry, including an outer curved portion 372 and an inner curved portion 374. The outer curved portion 372 can be disposed radially outward from the inner curved portion 374 relative to the opening 364 defined by the rear cover 330. In addition, the stepped geometry of the metal sheet 354 of the antenna component can include an intermediate step portion 376 disposed between the outer curved portion 372 and the inner curved portion 374. In at least one example, the inner curved portion 374 is disposed lower than the outer curved portion 372. The intermediate step portion 376 can connect the inner curved portion 374 and the outer curved portion 372 and span between the higher level or position of the outer curved portion 372 and the lower level or position of the inner curved portion 374.

Any number or variety of components in any of the configurations described with reference to FIGS. 3A-3C can be included alone or in combination in any other electronic device described herein with reference to other figures. The components can include any combination of the features described herein and can be arranged in any of the various configurations described herein. The structure and arrangement of components of a device, as well as the concepts regarding the use and operation of the components can apply not only to the specific examples discussed herein, but to any number of embodiments in any combination. Various examples of electronic devices and electronic device components including having various features in various arrangements are described above and below, with reference to FIGS. 1A-2 and 4-9.

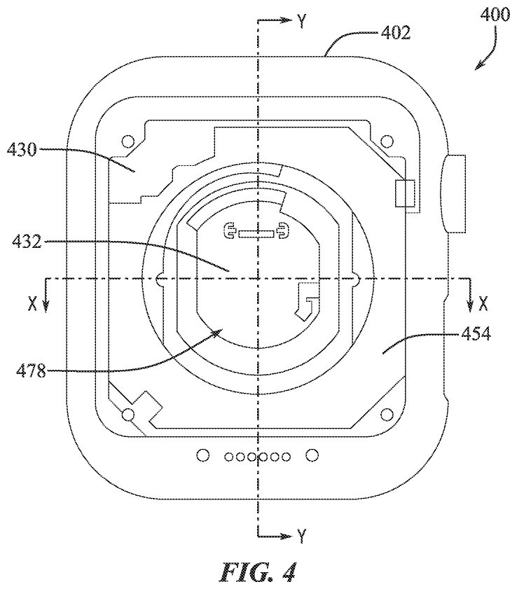

As shown in FIGS. 3B and 4, in at least one example of an electronic device 300, 400, the rear cover 330 defines a first opening 364 and the antenna component 454 defines a second opening 478 corresponding in position with the first opening 364, as shown in the top view of FIG. 4. In such an example, the rear cover 430 and antenna component 454 together define an opening in which the electromagnetically transparent component 432 can be disposed. In at least one example, the antenna component 454 can include a metal sheet 454 including a conductive material.

As noted above with reference to FIG. 3C, the antenna component of FIG. 4 can be embedded within the plastic body (referenced as 366 in FIG. 3C) of the rear cover 430. The illustrated example of FIG. 4 indicates the position of the antenna component 454 relative to the opening 432 of the rear cover 430, the housing 402 of the device 400, and the electromagnetically transparent component 432. However, when assembled and during use, the antenna component 454 can be embedded within the rear cover 430 such that the antenna component 454 is not visible or mostly not visible. In at least one example, the antenna component 454 can be insert molded into the plastic body of the rear cover 430.

Any number or variety of components in any of the configurations described with reference to FIG. 4 can be included alone or in combination in any other electronic device described herein with reference to other figures. The components can include any combination of the features described herein and can be arranged in any of the various configurations described herein. The structure and arrangement of components of a device, as well as the concepts regarding the use and operation of the components can apply not only to the specific examples discussed herein, but to any number of embodiments in any combination. Various examples of electronic devices and electronic device components including having various features in various arrangements are described above and below, with reference to FIGS. 1A-3C and 5A-9.

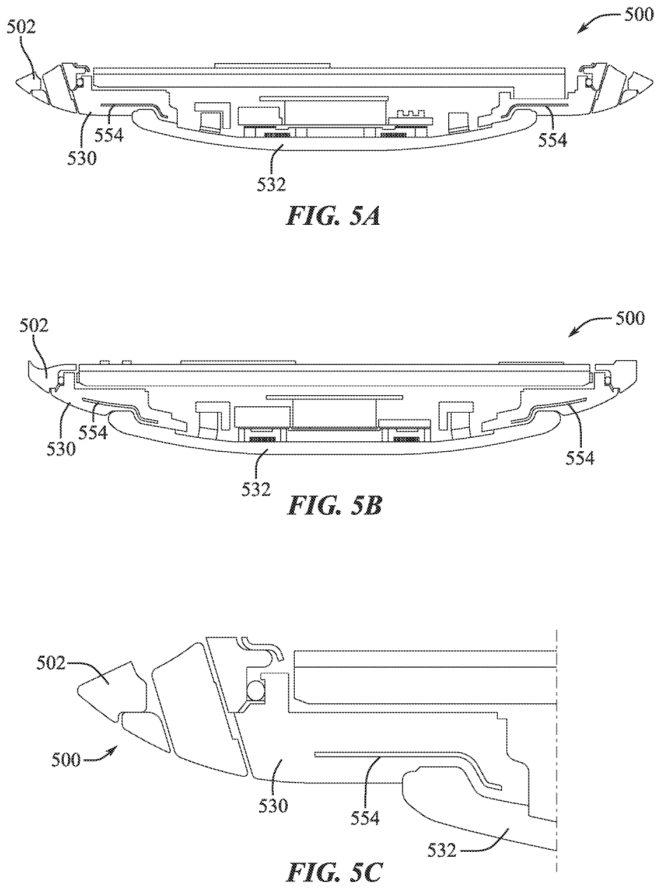

FIG. 5A illustrates a cross-sectional view of a device 500 similar to the device 400 shown in FIG. 4 taken along the orientation lines Y-Y indicated in FIG. 4. The device includes a housing 502, a rear cover 530 defining an opening in which an electromagnetically transparent component 532 is disposed, and various other internal components. In addition, the device 500 includes an antenna component 554 embedded within the rear cover. FIG. 5B illustrates a cross-sectional view of a device 500 similar to the device 400 shown in FIG. 4 taken along the orientation lines X-X indicated in FIG. 4. FIG. 5C illustrates a close-up view of the cross-sectional view of FIG. 5A. As shown in FIGS. 5A-5C, the antenna component can include a stepped geometry that varies depending on the orientation of the cross-sectional profile. In either view, the stepped geometry and curvature of the antenna component 554 correspond to the curvature of an outer surface of the rear cover 530.

In this way, the distance between the average vertical position of the antenna component 554 and another component of the antenna, such as a grounding plane or grounding component of the antenna of the device 500 can be maximized to improve antenna performance and sensitivity. The rear cover 530 can be curved at an external surface to form aesthetically pleasing transition contours between the housing 502 and the electromagnetically transparent component 532 and to improve or increase the contact between the user's wrist or skin and the electromagnetically transparent component 532 when the device 500 is donned. In this way, sensors and other detectors disposed in the device 500 can interact with the user's body through electromagnetically transparent component 532 with consistent contact.

In addition, as shown in FIGS. 5A-5C, the antenna component 532 can surround one or more internal components and be disposed peripherally around the electromagnetically transparent component 532 and/or the opening defined by the rear cover 530 in which the electromagnetically transparent component 532 is disposed. In this way, the antenna component 532 does not physically interfere in the space or position of any of the other internal components of the device 500. In addition, the antenna component 532 can structurally support and strengthen the rear cover 530 all the way or at least partially around the entire rear cover 530 surrounding and defining the opening in which the electromagnetically transparent component 532 is disposed.

Any number or variety of components in any of the configurations described with reference to FIGS. 5A-5C can be included alone or in combination in any other electronic device described herein with reference to other figures. The components can include any combination of the features described herein and can be arranged in any of the various configurations described herein. The structure and arrangement of components of a device, as well as the concepts regarding the use and operation of the components can apply not only to the specific examples discussed herein, but to any number of embodiments in any combination. Various examples of electronic devices and electronic device components including having various features in various arrangements are described above and below, with reference to FIGS. 1A-4 and 6A-9.

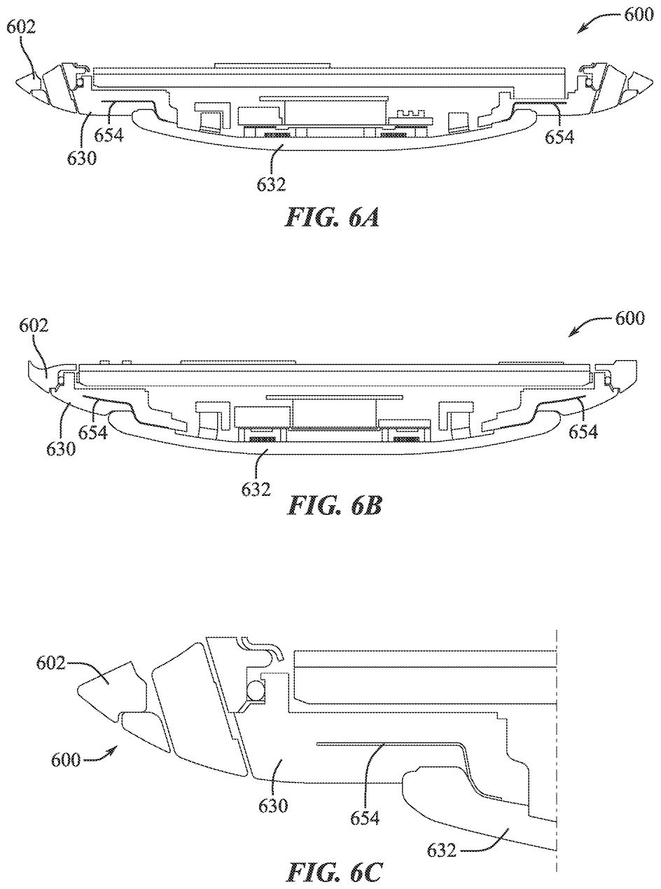

FIG. 6A illustrates a cross-sectional view of a device 600 similar to the device 400 shown in FIG. 4 taken along the orientation lines Y-Y indicated in FIG. 4. The device includes a housing 602, a rear cover 630 defining an opening in which an electromagnetically transparent component 632 is disposed, and various other internal components. In addition, the device 600 includes an antenna component 654 embedded within the rear cover.

FIG. 6B illustrates a cross-sectional view of a device 600 similar to the device 400 shown in FIG. 4 taken along the orientation lines X-X indicated in FIG. 4. FIG. 6C illustrates a close-up view of the cross-sectional view of FIG. 6A. As shown in FIGS. 6A-6C, the antenna component can include a stepped geometry that varies depending on the orientation of the cross-sectional profile. In either view, the stepped geometry and curvature of the antenna component 654 correspond to the curvature of an outer surface of the rear cover 630. The antenna component 654 illustrated in FIGS. 6A-6C, including the stepped geometry, curvature, position, shape, size, or other configuration is different than the curvature, position, shape, size, and configuration of the antenna component 554 shown in FIGS. 5A-5C.

In both examples, including the example of the antenna component 654 shown in FIGS. 6A-6C, the distance between the average vertical position of the antenna component 654 and another component of the antenna, such as a grounding plane or grounding component of the antenna of the device 600 can be maximized to improve antenna performance and sensitivity. The rear cover 630 can be curved at an external surface to form aesthetically pleasing transition contours between the housing 602 and the electromagnetically transparent component 632 and to improve or increase the contact between the user's wrist or skin and the electromagnetically transparent component 632 when the device 600 is donned. In this way, sensors and other detectors disposed in the device 600 can interact with the user's body through electromagnetically transparent component 632 with consistent contact.

In addition, as shown in FIGS. 6A-6C, the antenna component 632 can surround one or more internal components and be disposed peripherally around the electromagnetically transparent component 632 and/or the opening defined by the rear cover 630 in which the electromagnetically transparent component 632 is disposed. In this way, the antenna component 632 does not physically interfere in the space or position of any of the other internal components of the device 600. In addition, the antenna component 632 can structurally support and strengthen the rear cover 630 all the way or at least partially around the entire rear cover 630 surrounding and defining the opening in which the electromagnetically transparent component 632 is disposed.

Any number or variety of components in any of the configurations described with reference to FIGS. 6A-6C can be included alone or in combination in any other electronic device described herein with reference to other figures. The components can include any combination of the features described herein and can be arranged in any of the various configurations described herein. The structure and arrangement of components of a device, as well as the concepts regarding the use and operation of the components can apply not only to the specific examples discussed herein, but to any number of embodiments in any combination. Various examples of electronic devices and electronic device components including having various features in various arrangements are described above and below, with reference to FIGS. 1A-5C and 7-9.

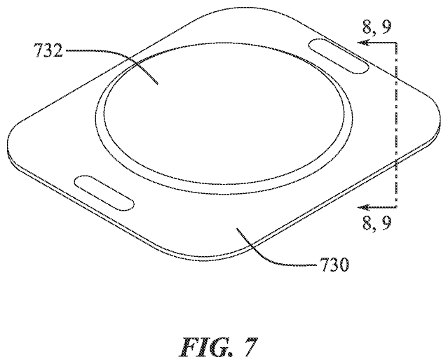

FIG. 7 shows a bottom perspective view of a rear cover 730 and an electromagnetically transparent component 732 disposed in an opening defined by the rear cover 730. The rear cover 330 can define an external surface of an electronic device, including any of the electronic device described herein and shown in the figures. In addition, though not shown in FIG. 7, a metal sheet 354 of an antenna component can be disposed within the rear cover 730 and the rear cover 730 can include a plastic body (similar to the body 366 labeled in FIG. 3C). In addition, in at least one example, a hard coat layer defining the external surface of the device and disposed on the body of the rear cover 730.

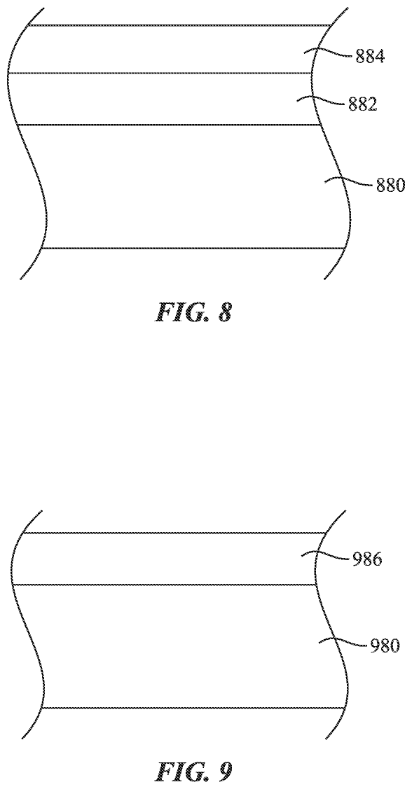

For example, as shown in FIG. 8, the body 880 of a rear cover can include a plastic material and a hard coat layer 884 can be disposed on the plastic body 880 of the rear cover. The hard coat layer 884 can define the external surface of the rear cover and the electronic device. In at least one example, the body 880 of the rear cover can include glass-filled nylon. In at least one example, the hard coat layer 884 can include a UV-curable hard coat material. In at least one example, the rear cover can further include a primer layer 882 disposed between the hard coat layer 884 and the body 880. The primer layer 882 can be disposed directly against the material of the body 880.

In another example, as shown in FIG. 9, a rear cover can include a hard coat layer 986 disposed directly against the body 980 without an intermediate primer layer disposed therebetween. In the illustrated example of FIG. 9, the hard coat layer 986 can include a UV-curable mono-coat forming an external surface of the rear cover and thus an external surface of the device of which the rear cover is a part. The hard coat layers 884 and 986, shown in FIGS. 8 and 9, respectively, can provide scratch resistant materials on the user facing external surface of the rear cover. The hard coat layers 884 and 986 can also provide various aesthetic options such as a matt finish to the rear cover of the device.

In at least one example, the hard coat layer 986 shown in FIG. 9 can include a mono-coat hard layer including a condensed primer and hard-coat material in one layer. This single mono-coat layer 986 can combine the chemistry of a primer with the UV curable chemistry of a hard-coat to provide durable bonding with the body 980 as well as sufficient hardness for protection of the rear cover. The single mono-coat layer 986 can provide excellent adhesion without the application of a primer layer. In other words, the application of the hard coat utilizes a single applicator instead of the two applicators utilized when using a primer. The mono-coat 986 shown in FIG. 9 can be relatively inexpensive to manufacture and provide a pleasing aesthetic appearance.

In one example, the UV-curable mono-coat layer 986 can include an indentation hardness between about 190 N/mm² and about 250 N/mm². In some examples, the indentation hardness of the UV-curable mono-coat layer 986 prevents chipping of the mono-coat without sacrificing chemical durability and strength. In some examples, the indentation hardness of the UV-curable mono-coat layer 986 can be in ranges between about 190 N/mm² and about 200 N/mm², between about 200 N/mm² and about 220 N/mm², between about 220 N/mm² and about 235 N/mm², or between about 235 N/mm² and about 250 N/mm².

In one example, the UV-curable mono-coat used to form the mono-coat layer 986 can include an acrylic polyol with a glass transition temperature of about 50° C. Glass transition is the gradual and reversible transition of the acrylic polyol from a hard and relatively brittle state into a viscous state as the temperature is increased. The glass-transition temperature of the acrylic polyol characterizes the range of temperatures over which this glass transition occurs.

The UV-curable mono-coat provides a good balance of crack resistance, scratch resistance, and chemical durability. The coating formulation can combine UV curable acrylic monomer(s) and thermal curable acrylic polyol resin. In at least one example, the UV-curable mono-coat can include an acrylic monomer(s) and an acrylic polyol between about 10% and about 20% (Hydroxyethyl)methacrylate, and between about 3% and about 7% Methacrylic acid by volume.

In some examples, the UV-curable mono-coat can include an acrylic polyol that contains between about 35% and about 45% Methyl methacrylate, between about 15% and about 25% Isobutyl methacrylate, and between about 15% and about 25% Ethylhexyl acrylate by volume. In one example, the UV-curable mono-coat can include an acrylic polyol that contains about 40% Methyl methacrylate, about 20% Isobutyl methacrylate, and about 20% Ethylhexyl acrylate by volume; and about 15% (Hydroxyethyl)methacrylate and about 5% Methacrylic acid by volume. The about 40% Methyl methacrylate and about 20% Isobutyl methacrylate can be included as acrylic monomers to control the glass transition temperature of the acrylic polyol. The about 20% Ethylhexyl acrylate can be included to provide and/or assist viscosity control. The about 15% (Hydroxyethyl)methacrylate can be included to provide and/or assist crosslinking and the about 5% Methacrylic acid can provide and/or assist adhesion to nylon (e.g., the glass-filled nylon of the plastic body).

While the present examples are provided as being UV curable, any number of curing processes and methodologies can be used to cure the UV-curable mono-coat including, but in no way limited to, an application of UV radiation, or a dual cure method. According to one example, a dual cure method for the present UV-curable mono-coat can include a drying step, followed by an application of UV radiation to accomplish a first cure. After the first cure, the mono-coat can be fully cured (second cure) via a baking process. Any combination of UV-radiation, drying, and baking can be used to vary the cure levels and resulting properties of the UV-curable mono-coat.

In some examples, the mono-coat layer can be applied in various thicknesses. According to one example, the mono-coat layer can be applied to the rear cover 730 in a ranges from approximately 8-25 um, approximately 10-15 um, or 10-25 um.

Any number or variety of components in any of the configurations described with reference to FIGS. 7-9 can be included alone or in combination in any other electronic device described herein with reference to other figures. The components can include any combination of the features described herein and can be arranged in any of the various configurations described herein. The structure and arrangement of components of a device, as well as the concepts regarding the use and operation of the components can apply not only to the specific examples discussed herein, but to any number of embodiments in any combination. Various examples of electronic devices and electronic device components including having various features in various arrangements are described above and below, with reference to FIGS. 1A-6C.

Any of the features or aspects of the devices and components discussed herein can be combined or included in any varied combination. For example, the design and shape of the components or devices is not limited in any way and can be formed by any number of processes, including those discussed herein. As used herein, the terms exterior, outer, interior, and inner are used for reference purposes only. An exterior or outer portion of a component can form a portion of an exterior surface of the component, but may not necessarily form the entire exterior of outer surface thereof. Similarly, the interior or inner portion of a component can form or define an interior or inner portion of the component, but can also form or define a portion of an exterior or outer surface of the component.

Various inventions have been described herein with reference to certain specific embodiments and examples. However, they will be recognized by those skilled in the art that many variations are possible without departing from the scope and spirit of the inventions disclosed herein, in that those inventions set forth in the claims below are intended to cover all variations and modifications of the inventions disclosed without departing from the spirit of the inventions. The terms “including:” and “having” come as used in the specification and claims shall have the same meaning as the term “including.”

To the extent applicable to the present technology, gathering and use of data available from various sources can be used to improve the delivery to users of invitational content or any other content that may be of interest to them. The present disclosure contemplates that in some instances, this gathered data may include personal information data that uniquely identifies or can be used to contact or locate a specific person. Such personal information data can include demographic data, location-based data, telephone numbers, email addresses, TWITTER® ID's, home addresses, data or records relating to a user's health or level of fitness (e.g., vital signs measurements, medication information, exercise information), date of birth, or any other identifying or personal information.

The present disclosure recognizes that the use of such personal information data, in the present technology, can be used to the benefit of users. For example, the personal information data can be used to deliver targeted content that is of greater interest to the user. Accordingly, use of such personal information data enables users to calculated control of the delivered content. Further, other uses for personal information data that benefit the user are also contemplated by the present disclosure. For instance, health and fitness data may be used to provide insights into a user's general wellness, or may be used as positive feedback to individuals using technology to pursue wellness goals.

The present disclosure contemplates that the entities responsible for the collection, analysis, disclosure, transfer, storage, or other use of such personal information data will comply with well-established privacy policies and/or privacy practices. In particular, such entities should implement and consistently use privacy policies and practices that are generally recognized as meeting or exceeding industry or governmental requirements for maintaining personal information data private and secure. Such policies should be easily accessible by users, and should be updated as the collection and/or use of data changes. Personal information from users should be collected for legitimate and reasonable uses of the entity and not shared or sold outside of those legitimate uses. Further, such collection/sharing should occur after receiving the informed consent of the users. Additionally, such entities should consider taking any needed steps for safeguarding and securing access to such personal information data and ensuring that others with access to the personal information data adhere to their privacy policies and procedures. Further, such entities can subject themselves to evaluation by third parties to certify their adherence to widely accepted privacy policies and practices. In addition, policies and practices should be adapted for the particular types of personal information data being collected and/or accessed and adapted to applicable laws and standards, including jurisdiction-specific considerations. For instance, in the US, collection of or access to certain health data may be governed by federal and/or state laws, such as the Health Insurance Portability and Accountability Act (HIPAA); whereas health data in other countries may be subject to other regulations and policies and should be handled accordingly. Hence different privacy practices should be maintained for different personal data types in each country.

Despite the foregoing, the present disclosure also contemplates embodiments in which users selectively block the use of, or access to, personal information data. That is, the present disclosure contemplates that hardware and/or software elements can be provided to prevent or block access to such personal information data. For example, in the case of advertisement delivery services, the present technology can be configured to allow users to select to “opt in” or “opt out” of participation in the collection of personal information data during registration for services or anytime thereafter. In another example, users can select not to provide mood-associated data for targeted content delivery services. In yet another example, users can select to limit the length of time mood-associated data is maintained or entirely prohibit the development of a baseline mood profile. In addition to providing “opt in” and “opt out” options, the present disclosure contemplates providing notifications relating to the access or use of personal information. For instance, a user may be notified upon downloading an app that their personal information data will be accessed and then reminded again just before personal information data is accessed by the app.

Moreover, it is the intent of the present disclosure that personal information data should be managed and handled in a way to minimize risks of unintentional or unauthorized access or use. Risk can be minimized by limiting the collection of data and deleting data once it is no longer needed. In addition, and when applicable, including in certain health related applications, data de-identification can be used to protect a user's privacy. De-identification may be facilitated, when appropriate, by removing specific identifiers (e.g., date of birth, etc.), controlling the amount or specificity of data stored (e.g., collecting location data a city level rather than at an address level), controlling how data is stored (e.g., aggregating data across users), and/or other methods.

Therefore, although the present disclosure broadly covers use of personal information data to implement one or more various disclosed embodiments, the present disclosure also contemplates that the various embodiments can also be implemented without the need for accessing such personal information data. That is, the various embodiments of the present technology are not rendered inoperable due to the lack of all or a portion of such personal information data. For example, content can be selected and delivered to users by inferring preferences based on non-personal information data or a bare minimum amount of personal information, such as the content being requested by the device associated with a user, other non-personal information available to the content delivery services, or publicly available information.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not target to be exhaustive or to limit the embodiments to the precise forms disclosed. It will be apparent to one of ordinary skill in the art that many modifications and variations are possible in view of the above teachings.

What is claimed is:

1. An electronic device, comprising:
a housing defining an internal volume and an opening;
a rear cover disposed in the opening, an inner surface of the rear cover defining the internal volume; and
a conductive antenna component embedded within the rear cover.

2. The electronic device of claim 1, wherein the conductive antenna component is disposed outside the internal volume.

3. The electronic device of claim 2, wherein the antenna component is entirely embedded within the rear cover.

4. The electronic device of claim 1, wherein an outer surface of the rear cover defines an external surface of the electronic device.

5. The electronic device of claim 4, wherein:
the rear cover extends across a thickness defined between the outer surface and the inner surface; and
the antenna component is disposed within the thickness.

6. The electronic device of claim 1, wherein the rear cover comprises a plastic.

7. The electronic device of claim 1, wherein:
the rear cover defines a first opening; and
the antenna component defines a second opening corresponding in position with the first opening.

8. An electronic device housing, comprising:
a sidewall defining a rear opening;
a rear cover disposed in the opening and defining an external surface; and
a metal sheet disposed within the rear cover;
wherein the rear cover comprises:
a plastic body; and
a hard coat layer disposed on the plastic body and defining the external surface.

9. The electronic device housing of claim 8, wherein the metal sheet comprises an antenna.

10. The electronic device housing of claim 9, wherein the antenna is embedded within the plastic body.

11. The electronic device housing of claim 10, wherein the antenna is insert molded into the plastic body.

12. The electronic device housing of claim 8, wherein the plastic body comprises a glass-filled nylon.

13. The electronic device housing of claim 8, further comprising a primer layer disposed between the hard coat layer and the plastic body.

14. The electronic device housing of claim 8, wherein the hard coat layer comprises a UV-curable material.

15. The electronic device housing of claim 8, wherein the hard coat layer comprises a UV-curable mono-coat including an acrylic polyol disposed directly on the plastic body.

16. The electronic device housing of claim 15, wherein the UV-curable mono-coat comprises an indentation hardness between about 190 N/mm² and about 250 N/mm².

17. The electronic device housing of claim 15, wherein the glass transition temperature of the acrylic polyol is about 50° C.

18. The electronic device housing of claim 15, wherein the acrylic polyol further comprises an acrylic monomer; and
wherein the acrylic polyol comprises between about 10% and about 20% (hydroxyethyl)methacrylate, and between about 3% and about 7% methacrylic acid by volume.

19. A rear cover of an electronic device, comprising:
a non-conductive body having an external surface with a first curvature; and
an antenna component embedded in the non-conductive body, the antenna component having a second curvature corresponding to the first curvature.

20. The rear cover of an electronic device of claim 19, wherein the second curvature comprises a stepped curved geometry.

21. The rear cover of an electronic device of claim 20, wherein the stepped curved geometry comprises an outer curved portion and an inner curved portion.

22. The rear cover of an electronic device of claim 21, wherein the stepped curved geometry further comprises an intermediate step portion disposed between the outer curved portion and the inner curved portion.

23. The rear cover of an electronic device of claim 22, wherein the inner curved portion is disposed lower than the outer curved portion.
